(19) United States
(12) Patent Application Publication
(10) Pub. No.: US 2025/0054772 A1
(43) Pub. Date: Feb. 13, 2025

(54) HEAT TREATMENT METHOD FOR HEATING SUBSTRATE BY LIGHT IRRADIATION

(71) Applicant: SCREEN Holdings Co., Ltd., Kyoto (JP)

(72) Inventor: Hideaki TANIMURA, Kyoto-shi (JP)

(21) Appl. No.: 18/677,613

(22) Filed: May 29, 2024

(30) Foreign Application Priority Data
Aug. 7, 2023 (JP) 2023-128676

(51) Int. Cl. H01L 21/324; H01L 21/67; H01L 21/687

(52) U.S. Cl. CPC H01L 21/324; H01L 21/67115; H01L 21/6875

(57) ABSTRACT

A semiconductor wafer is preheated to a predetermined preheating temperature. Thereafter, flash heating for heating a front surface of the semiconductor wafer is performed by irradiating the front surface with flashes of light. The flash heating includes a first flash heating process in which the temperature of the front surface of the semiconductor wafer is increased at a first temperature increase rate, and a second flash heating process in which the temperature of the front surface of the semiconductor wafer is increased at a second temperature increase rate higher than the first temperature increase rate. The preheating temperature is made lower than a reaction temperature, and a shortage of the preheating is compensated for by the first flash heating process. Finally, the second flash heating process increases the temperature of the front surface of the semiconductor wafer to a target treatment temperature.

### BACKGROUND OF THE INVENTION

### Field of the Invention

The present invention relates to a heat treatment method which irradiates a substrate with light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating with low thermal history (providing a small amount of heat), e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time to result in a low thermal history, thereby achieving only the activation of the impurities without deep diffusion of the impurities. In general, it is difficult for flash irradiation alone to cause the surface temperature of the semiconductor wafer to reach a target temperature. For this reason, the surface of the semiconductor wafer preheated to a predetermined temperature is irradiated with a flash of light (as disclosed, for example, in Japanese Patent Application Laid-Open No. 2018-101760).

The flash lamp annealing for an extremely short irradiation time period can suppress the deep diffusion of impurities. In recent years, however, there has been a demand to achieve high activation while suppressing diffusion on the order of angstroms. This requires a further reduction in thermal history in the flash lamp annealing.

The application of new materials typified by germanium in place of silicon for the manufacture of semiconductor devices has also been considered. Germanium has the properties of having a lower melting point than silicon and reacting with oxygen and other atmospheric gases even at low temperatures although having high carrier mobility. Thus, processes with a lower thermal history are required for the application of the flash lamp annealing to the new materials such as germanium.

In addition, 3-D semiconductor devices exemplified by CFETs (Complementary Field Effect Transistors) have also been considered. CFETs have a stacked structure in which nMOS transistors are stacked on pMOS transistors. When the flash lamp annealing is performed for the formation of the nMOS transistors serving as an upper layer, it is necessary to prevent excessive thermal effects on the already completed pMOS transistors serving as a lower layer from deteriorating device properties. In other words, a further reduction in thermal history is required for the flash lamp annealing also in this case.

For these various purposes, even lower thermal history is required for the flash lamp annealing. In general flash lamp annealing, a semiconductor wafer is preheated (assist-heated) to a predetermined temperature by halogen lamps and the like before the flash irradiation is performed. This is because it is difficult for the flash irradiation alone to cause the surface temperature of the semiconductor wafer to reach the target temperature, as mentioned above.

However, the preheating using the halogen lamps and the like is significantly longer in heating time period and extremely slow in the rate of temperature increase, as compared to the flash heating using the flash irradiation. Typically, the heating time period for the preheating is on the order of seconds, whereas the heating time period for the flash heating is on the order of milliseconds. Also, the rate of temperature increase during the preheating is several hundred ° C./sec, whereas the rate of temperature increase during the flash heating is several million ° C./sec. Thus, the amount of heat given to the semiconductor wafer during the preheating is compelled to be large, which in turn constitutes an obstacle to the lower thermal history in the flash lamp annealing.

### SUMMARY

The present invention is intended for a method of irradiating a substrate with light to heat the substrate.

According to one aspect of the present invention, the method comprises the steps of: (a) irradiating the substrate with light from a continuous lighting lamp to heat the substrate to a preheating temperature lower than a reaction temperature at which a reaction occurs in the substrate; and (b) irradiating a front surface of the substrate with a flash of light from a flash lamp to increase the temperature of the front surface in multiple stages to a treatment temperature higher than the reaction temperature so that the temperature increase rate of the front surface is higher in a later stage, the step (b) being performed after the step (a).

The method is capable of reducing the amount of heat given to the substrate, as compared to preheating using only the continuous lighting lamp.

Preferably, the step (b) includes the steps of: (b-1) irradiating the front surface of the substrate with a flash of light to increase the temperature of the front surface at a first temperature increase rate to an intermediate temperature; and (b-2) irradiating the front surface of the substrate with a flash of light to increase the temperature of the front surface at a second temperature increase rate to the treatment temperature, the second temperature increase rate being higher than the first temperature increase rate, the step (b-2) being subsequent to the step (b-1).

This further reduces the amount of heat given to the substrate.

It is therefore an object of the present invention to reduce the amount of heat given to a substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus for carrying out a heat treatment method according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a diagram showing a driving circuit for a flash lamp;

FIG. 9 is a flow diagram showing a procedure for the heat treatment method according to the present invention;

FIG. 10 is a graph showing changes in temperature of a semiconductor wafer; and

FIG. 11 is a graph showing changes in temperature of a front surface of the semiconductor wafer subjected to two-stage flash heating.

### DESCRIPTION OF THE PREFERRED EMBODIMENTS

A preferred embodiment according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

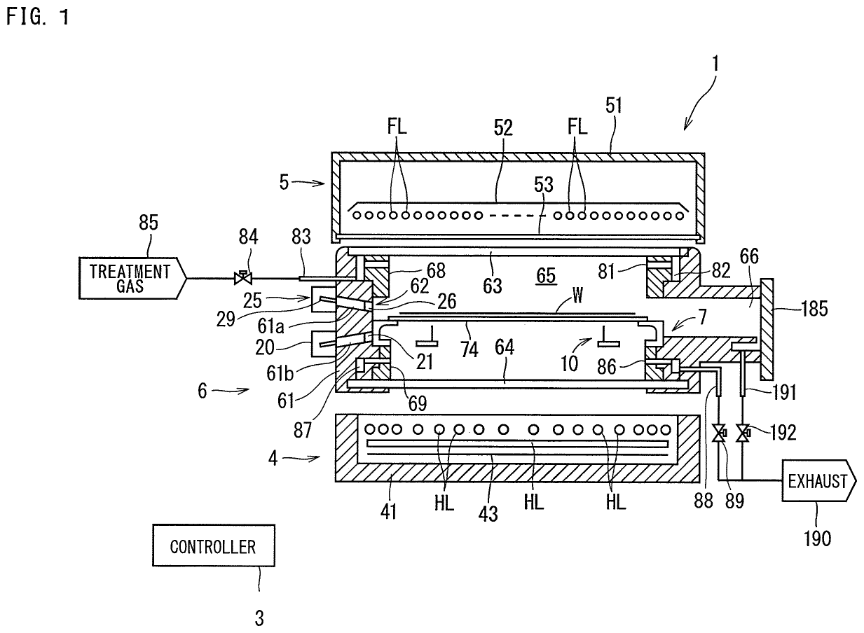

FIG. 1 is a longitudinal sectional view showing a configuration of a heat treatment apparatus 1 for carrying out a heat treatment method according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm (in the present preferred embodiment, 300 mm). It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an infrared sensor 29 of an upper radiation thermometer 25. The through hole 61b is a cylindrical hole for directing infrared light emitted from a lower surface of the semiconductor wafer W therethrough to a lower radiation thermometer 20. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect main surfaces of the semiconductor wafer W held by the susceptor 74. A transparent window 26 made of calcium fluoride material transparent to infrared light in a wavelength range measurable with the upper radiation thermometer 25 is mounted to an end portion of the through hole 61a which faces the heat treatment space 65. A transparent window 21 made of barium fluoride material transparent to infrared light in a wavelength range measurable with the lower radiation thermometer 20 is mounted to an end portion of the through hole 61b which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

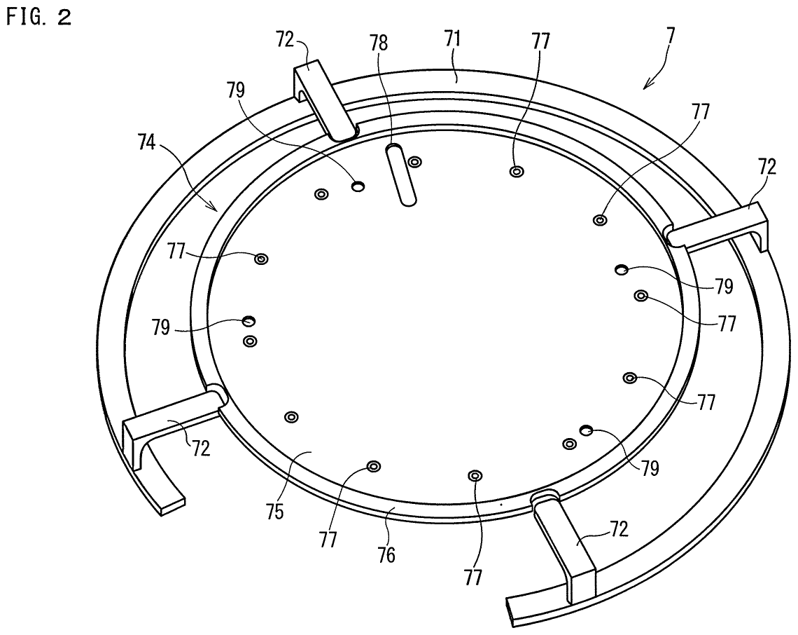

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

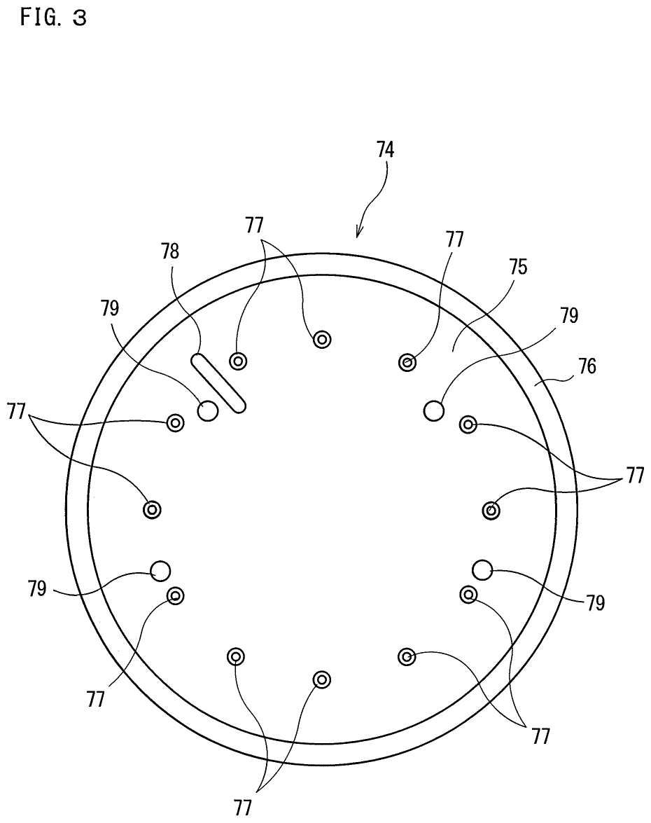

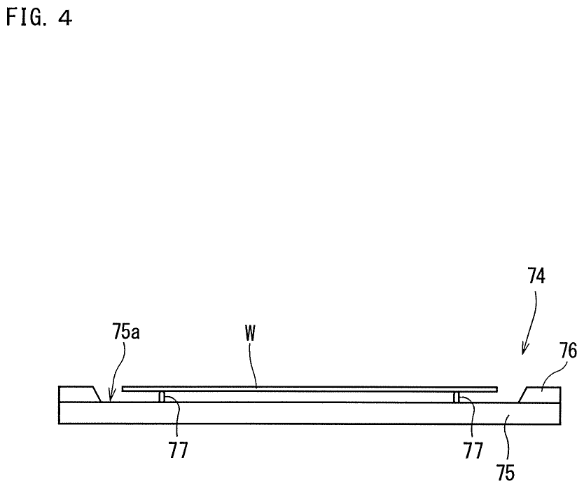

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

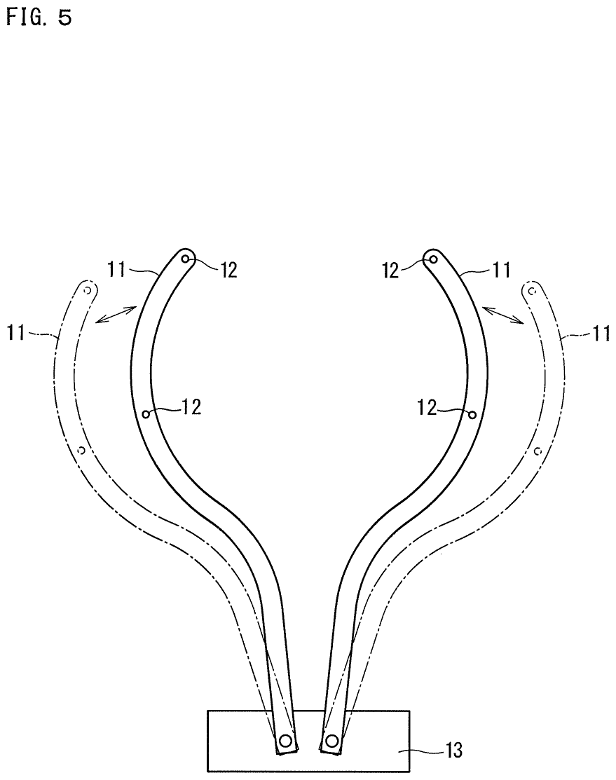

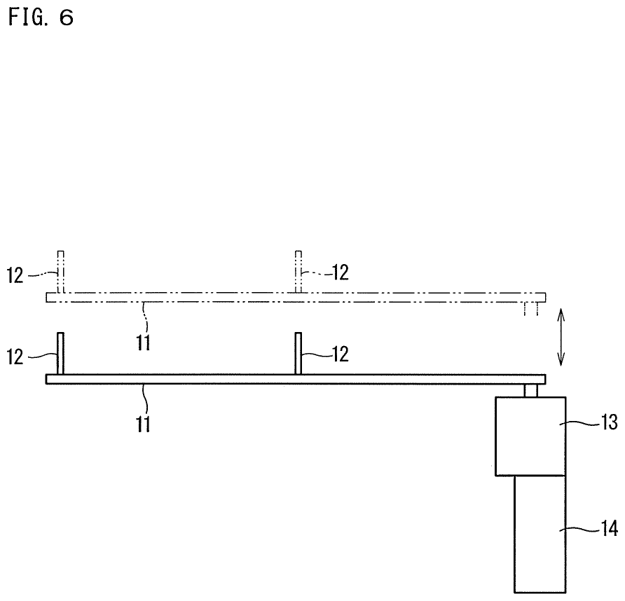

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

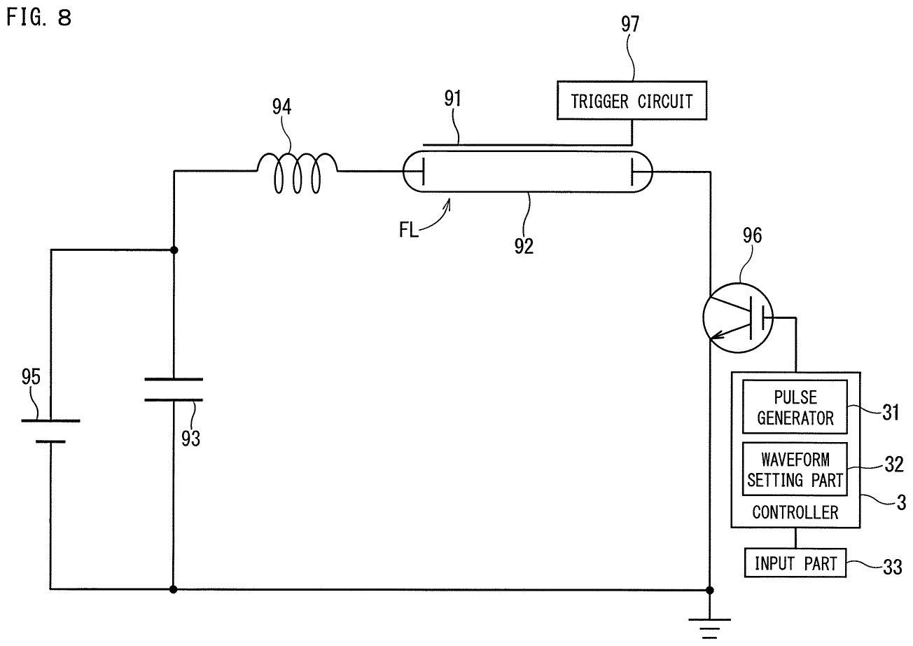

FIG. 8 is a diagram showing a driving circuit for each flash lamp FL. As illustrated in FIG. 8, a capacitor 93, a coil 94, a flash lamp FL, and an IGBT (insulated-gate bipolar transistor) 96 are connected in series. Also as shown in FIG. 8, the controller 3 includes a pulse generator 31 and a waveform setting part 32, and is connected to an input part 33. Examples of the input part 33 used herein include various known input devices such as a keyboard, a mouse, and a touch panel. The waveform setting part 32 sets the waveform of a pulse signal, based on an input from the input part 33, and the pulse generator 31 generates the pulse signal in accordance with that waveform.

The flash lamp FL includes a rod-shaped glass tube (discharge tube) 92 containing xenon gas sealed therein and having positive and negative electrodes provided on opposite ends thereof, and a trigger electrode 91 attached to the outer peripheral surface of the glass tube 92. A power supply unit 95 applies a predetermined voltage to the capacitor 93, and the capacitor 93 is charged in accordance with the applied voltage (charging voltage). A trigger circuit 97 is capable of applying a high voltage to the trigger electrode 91. The timing of the voltage application from the trigger circuit 97 to the trigger electrode 91 is under the control of the controller 3.

The IGBT 96 is a bipolar transistor which includes a MOSFET (Metal Oxide Semiconductor Field effect transistor) incorporated in the gate portion thereof, and is also a switching element suitable for handling a large amount of power. The pulse generator 31 in the controller 3 applies the pulse signal to the gate of the IGBT 96. When a voltage (“High” voltage) not less than a predetermined level is applied to the gate of the IGBT 96, the IGBT 96 turns on. When a voltage (“Low” voltage) less than the predetermined level is applied to the gate of the IGBT 96, the IGBT 96 turns off. In this manner, the driving circuit including the flash lamp FL is turned on and off by the IGBT 96. By turning the IGBT 96 on and off, a connection between the flash lamp FL and the capacitor 93 corresponding thereto is made and broken, so that the current flowing through the flash lamp FL is on-off controlled.

Even if, with the capacitor 93 in the charged state, the IGBT 96 turns on to apply a high voltage across the electrodes of the glass tube 92, no electricity will flow through the glass tube 92 in a normal state because the xenon gas is electrically insulative. However, when the trigger circuit 97 applies a high voltage to the trigger electrode 91 to produce an electrical breakdown, an electrical discharge between the electrodes causes a current to flow momentarily in the glass tube 92, so that xenon atoms or molecules are excited at this time to cause light emission.

The driving circuit as shown in FIG. 8 is provided individually for each of the flash lamps FL provided in the flash heating part 5. In the present preferred embodiment, 30 driving circuits each as shown in FIG. 8 are provided in corresponding relation to the 30 flash lamps FL arranged in a plane. Thus, the current flowing through each of the 30 flash lamps FL is individually on-off controlled by the IGBT 96.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 is a light irradiator that directs light from under the chamber 6 through the lower chamber window 64 toward the heat treatment space 65 to heat the semiconductor wafer W by means of the halogen lamps HL.

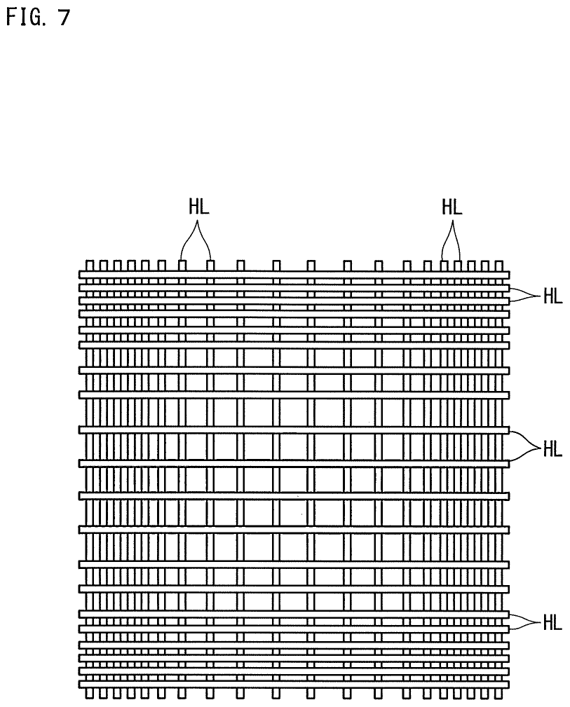

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

As shown in FIG. 1, the heat treatment apparatus 1 includes the upper radiation thermometer 25 and the lower radiation thermometer 20. The upper radiation thermometer 25 is provided obliquely above the semiconductor wafer W held by the susceptor 74, and receives the infrared radiation emitted from the upper surface of the semiconductor wafer W to measure the temperature of the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of flash irradiation. On the other hand, the lower radiation thermometer 20 is provided obliquely below the semiconductor wafer W held by the susceptor 74, and receives the infrared radiation emitted from the lower surface of the semiconductor wafer W to measure the temperature of the lower surface of the semiconductor wafer W.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 1 proceed. Also, the controller 3 includes the pulse generator 31 and the waveform setting part 32 (with reference to FIG. 8). The waveform setting part 32 sets the waveform of the pulse signal, based on an input from the input part 33, and the pulse generator 31 outputs the pulse signal to the gate of the IGBT 96 in accordance with the waveform.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

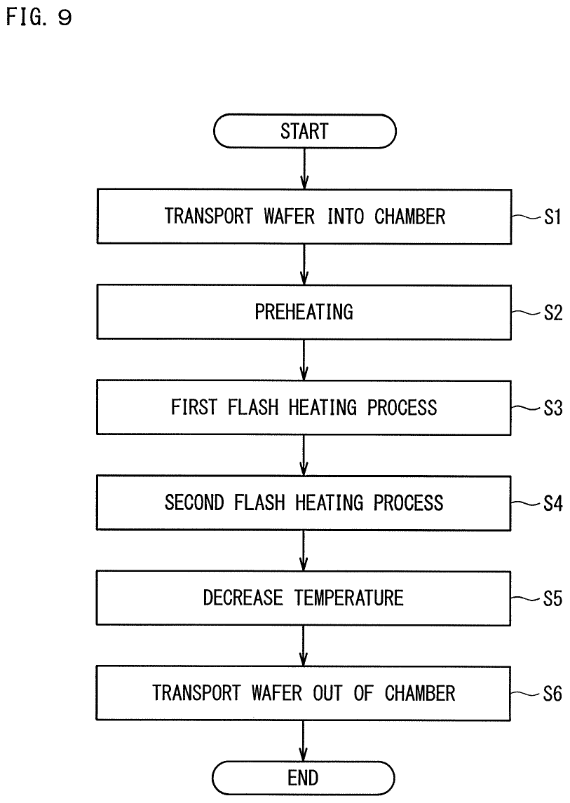

Next, a procedure for the heat treatment method according to the present invention will be described. FIG. 9 is a flow diagram showing the procedure for the heat treatment method according to the present invention. The semiconductor wafer W to be treated in the present preferred embodiment is a semiconductor substrate mainly composed of silicon. The semiconductor wafer W of silicon is previously implanted with impurities such as phosphorus (P) or boron (B) to a predetermined depth, for example, by an ion implantation method.

First, the semiconductor wafer W doped with impurities is transported into the chamber 6 (Step S1). When the semiconductor wafer W is transported into the chamber 6, the valve 84 for supply of gas is opened, and the valves 89 and 192 for exhaust of gas are opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports the semiconductor wafer W through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof implanted with the impurities is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heating part 4 turn on simultaneously to start preheating (or assist-heating) (Step S2). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

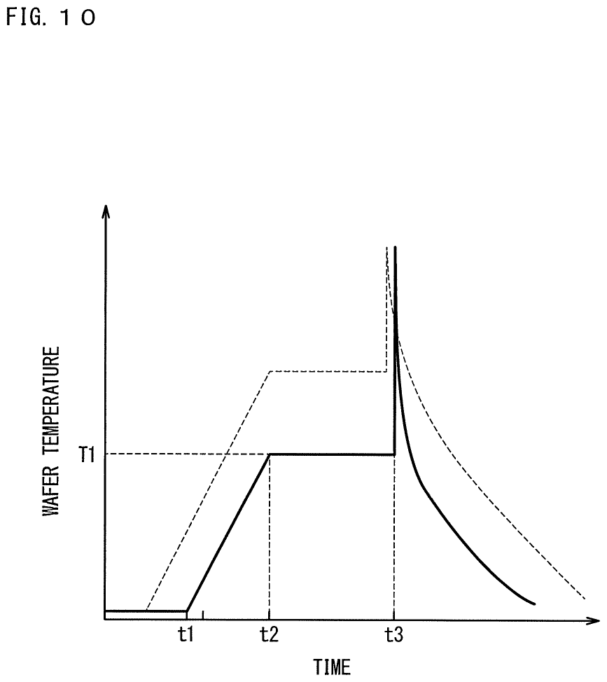

FIG. 10 is a graph showing changes in temperature of the semiconductor wafer W. At time t1, the halogen lamps HL turn on, so that the increase in temperature of the semiconductor wafer W starts. The temperature of the semiconductor wafer W is measured by the lower radiation thermometer 20 when the halogen lamps HL perform the preheating. Specifically, the lower radiation thermometer 20 receives infrared radiation emitted from the lower surface of the semiconductor wafer W held by the susceptor 74 through the opening 78 and passing through the transparent window 21 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the lower radiation thermometer 20. In this manner, the lower radiation thermometer 20 is a radiation thermometer for controlling the temperature of the semiconductor wafer W during the preheating.

The preheating temperature T1 in the case of the semiconductor wafer W of silicon is between 400° C. and 700° C. If the preheating temperature T1 is less than 400° C., it is difficult to increase the temperature of the front surface of the semiconductor wafer W to a required treatment temperature T3 during subsequent flash heating. On the other hand, if the preheating temperature T1 exceeds 700° C., the impurities implanted in the semiconductor wafer W starts diffusing. In other words, the preheating temperature T1 is lower than a reaction temperature at which a reaction (impurity diffusion in the present preferred embodiment) occurs in the semiconductor wafer W.

After the temperature of the semiconductor wafer W reaches the preheating temperature T1 at time t2, the controller 3 maintains the temperature of the semiconductor wafer W at the preheating temperature T1 for a short time. Specifically, at the point in time when the temperature of the semiconductor wafer W measured by the lower radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL in the flash heating part 5 irradiate the front surface of the semiconductor wafer W held by the susceptor 74 with a flash of light at time t3 when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

For the flash irradiation from each of the flash lamps FL, the power supply unit 95 accumulates an electric charge in the capacitor 93 at a predetermined charging voltage in advance. Then, with the capacitor 93 in the charged state, the pulse generator 31 in the controller 3 outputs a pulse signal to the IGBT 96 to drive the IGBT 96 on and off.

The waveform of the pulse signal is specified, for example, by inputting from the input part 33 a recipe that is a sequence of defined parameters including a time interval (ON time) equivalent to the pulse width and a time interval (OFF time) between pulses. After an operator inputs such a recipe from the input part 33 to the controller 3, the waveform setting part 32 in the controller 3 sets a pulse waveform having repeated ON and OFF time intervals in accordance with the recipe. Then, the pulse generator 31 outputs the pulse signal in accordance with the pulse waveform set by the waveform setting part 32. As a result, the pulse signal having the set waveform is applied to the gate of the IGBT 96 to control the driving on and off of the IGBT 96. Specifically, the IGBT 96 is on when the pulse signal inputted to the gate of the IGBT 96 is on, and the IGBT 96 is off when the pulse signal is off.

In synchronism with the turning on of the pulse signal outputted from the pulse generator 31, the controller 3 controls the trigger circuit 97 to apply a high voltage (trigger voltage) to the trigger electrode 91. The pulse signal is inputted to the gate of the IGBT 96, with the electrical charges stored in the capacitor 93, and the high voltage is applied to the trigger electrode 91 in synchronism with the turning on of the pulse signal, whereby a current flows across the electrodes of the glass tube 92 when the pulse signal is on. The resultant excitation of xenon atoms or molecules induces light emission.

In this manner, the 30 flash lamps FL of the flash heating part 5 emit light, so that the front surface of the semiconductor wafer W held by the holder 7 is irradiated with flashes of light. If such a flash lamp FL emits light without using the IGBT 96, the electrical charges stored in the capacitor 93 are consumed momentarily by emitting light only once, so that the output waveform from the flash lamp FL exhibits a single simple pulse having a width on the order of 0.1 to 10 milliseconds. On the other hand, the IGBT 96 serving as a switching element is connected in the circuit and the pulse signal is outputted to the gate of the IGBT 96 according to the present preferred embodiment. Thus, the IGBT 96 intermittently supplies the electrical charges from the capacitor 93 to the flash lamp FL to effect on-off control of the current flowing through the flash lamp FL. As a result, the light emission from the flash lamp FL is accordingly chopper-controlled, which allows the electrical charges stored in the capacitor 93 to be consumed in a divided manner. This enables the flash lamp FL to repeatedly flash on and off in an extremely short time. It should be noted that, before the value of the current flowing through the circuit reaches exactly zero, the next pulse is applied to the gate of the IGBT 96 to increase the current value again. For this reason, the emission output never reaches exactly zero even while the flash lamp FL repeatedly flashes on and off.

The IGBT 96 effects on-off control of the current flowing through the flash lamp FL to freely define the light emission pattern (time waveform of light emission outputs) of the flash lamp FL, thereby freely adjusting a light emission time period and a light emission intensity. The on-off driving pattern of the IGBT 96 is defined by the time interval equivalent to the pulse width and the time interval between the pulses inputted from the input part 33. That is, the incorporation of the IGBT 96 into the driving circuit for the flash lamp FL allows the light emission pattern of the flash lamp FL to be freely defined only by suitably setting the time interval equivalent to the pulse width and the time interval between the pulses inputted from the input part 33.

Specifically, for example, increasing the ratio of the time interval equivalent to the pulse width to the time interval between the pulses inputted from the input part 33 increases the current flowing through the flash lamp FL to increase the light emission intensity. On the other hand, decreasing the ratio of the time interval equivalent to the pulse width to the time interval between the pulses inputted from the input part 33 decreases the current flowing through the flash lamp FL to decrease the light emission intensity. When the ratio of the time interval equivalent to the pulse width to the time interval between the pulses inputted from the input part 33 is appropriately controlled, the light emission intensity of the flash lamp FL is maintained constant. Further, increasing the total time of a combination of the time interval equivalent to the pulse width and the time interval between the pulses inputted from the input part 33 causes the current to continue flowing through the flash lamp FL for a relatively long time, thereby increasing the light emission time period of the flash lamp FL. The light emission time period of the flash lamp FL is set appropriately between 0.1 and 100 milliseconds. The charging voltage to the capacitor 93 and the waveform of the light emission pattern of the flash lamp FL define the maximum attained temperature of the front surface of the semiconductor wafer W and the amount of heat inputted to the semiconductor wafer W.

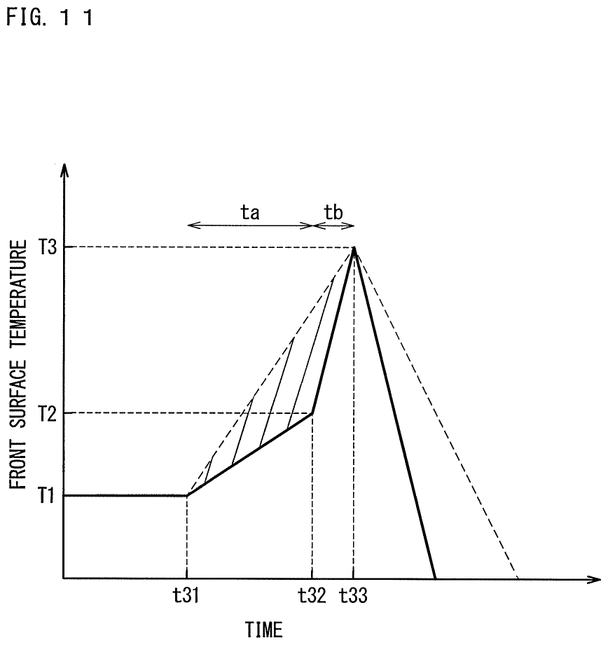

In the present preferred embodiment, the pulse signal applied to the gate of the IGBT 96 is set so that the light emission pattern of the flash lamp FL is that for a two-stage flash heating including: a first flash heating process in which the temperature of the front surface of the semiconductor wafer W is increased at a first temperature increase rate; and a second flash heating process in which the temperature of the front surface of the semiconductor wafer W is increased at a second temperature increase rate. FIG. 11 is a graph showing changes in temperature of the front surface of the semiconductor wafer W subjected to the two-stage flash heating. FIG. 11 is an enlarged view of an area around the time t3 of FIG. 10. The front surface of the semiconductor wafer W is doped with impurities.

From time t31 to time t32, a first stage of flash irradiation from the flash lamp FL is performed, whereby the first flash heating process is performed in which the temperature of the front surface of the semiconductor wafer W is increased at the first temperature increase rate (Step S3). In the first flash heating process, the temperature of the front surface of the semiconductor wafer W is increased from the preheating temperature T1 to an intermediate temperature T2 at the first temperature increase rate. In other words, the front surface temperature of the semiconductor wafer W reaches the intermediate temperature T2 at the time t32. By applying a pulse signal in which the ratio of the time interval equivalent to the pulse width to the time interval between the pulses is a first ratio to the IGBT 96, the current flowing through the flash lamp FL increases gradually. This achieves the first flash heating process in which the temperature of the front surface of the semiconductor wafer W is increased at the first temperature increase rate.

The heating time period ta of the first flash heating process from the time t31 to the time t32 is not less than 3 milliseconds. Preferably, the heating time period ta of the first flash heating process is between 3 and 40 milliseconds. The intermediate temperature T2 is between 600° C. and 1000° C. Preferably, the intermediate temperature T2 is between 700° C. and 1000° C.

From the time t32 to time t33, a second stage of flash irradiation from the flash lamp FL is subsequently performed, whereby the second flash heating process is performed in which the temperature of the front surface of the semiconductor wafer W is increased at the second temperature increase rate (Step S4). In the second flash heating process, the temperature of the front surface of the semiconductor wafer W is increased from the intermediate temperature T2 to the treatment temperature T3 at the second temperature increase rate. In other words, the front surface temperature of the semiconductor wafer W reaches the treatment temperature T3 at the time t33. The second temperature increase rate is higher than the first temperature increase rate. The treatment temperature T3 is the maximum attained temperature of the front surface of the semiconductor wafer W in a series of heat treatment processes, and is higher than the preheating temperature T1 and the intermediate temperature T2 as a matter of course. By applying a pulse signal in which the ratio of the time interval equivalent to the pulse width to the time interval between the pulses is a second ratio higher than the first ratio to the IGBT 96, the current flowing through the flash lamp FL further increases. This achieves the second flash heating process in which the temperature of the front surface of the semiconductor wafer W is increased at the second temperature increase rate.

The heating time period tb of the second flash heating process from the time t32 to the time t33 is not greater than 2 milliseconds. Preferably, the heating time period tb of the second flash heating process is between 0.1 and 2 milliseconds. That is, the heating time period ta of the first flash heating process is longer than the heating time period tb of the second flash heating process. The treatment temperature T3 is between 1100° C. and 1300° C., and is higher than the reaction temperature of the semiconductor wafer W. The second flash heating process causes the temperature of the front surface of the semiconductor wafer W to reach the treatment temperature T3, thereby activating the impurities implanted in the front surface. It should be noted that the abscissa (time axis) of FIG. 10 has a time scale of seconds, whereas the abscissa of FIG. 11 has a time scale of milliseconds. Thus, the times t31 to t33 in FIG. 11 are shown as overlaid on the time t3 in FIG. 10.

At the time t33, the pulse signal applied to the IGBT 96 turns off to stop the emission of flashes of light from the flash lamp FL, so that the front surface temperature of the semiconductor wafer W decreases rapidly (Step S5). Thereafter, the halogen lamps HL also turn off. This causes the temperature of the semiconductor wafer W to decrease rapidly from the preheating temperature T1 (with reference to FIG. 10). The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 to the outside. Thus, the heating treatment of the semiconductor wafer W in the heat treatment apparatus 1 is completed (Step S6). The upper radiation thermometer 25 may be used to measure the front surface temperature of the semiconductor wafer W which rapidly increases and decreases. The upper radiation thermometer 25, which measures the front surface temperature of the semiconductor wafer W at extremely short sampling intervals, is capable of following rapid changes, if any, in the front surface temperature of the semiconductor wafer W during the flash irradiation.

In the present preferred embodiment, the semiconductor wafer W is preheated to the preheating temperature T1 by irradiating the semiconductor wafer W implanted with impurities with light from the halogen lamps HL, and the flash heating is thereafter performed which heats the front surface of the semiconductor wafer W for not greater than one second by irradiating the front surface with flashes of light from the flash lamps FL. The preheating temperature T1 is made lower than the reaction temperature at which impurity diffusion occurs. In the conventional methods, a large amount of heat has been given to the semiconductor wafer W during the preheating. However, the preheating temperature T1 made lower than the reaction temperature at which a reaction occurs in the semiconductor wafer W makes the amount of heat given to the semiconductor wafer W low to prevent the diffusion of impurities.

However, if the preheating temperature T1 is low, there is a danger that the front surface temperature of the semiconductor wafer W cannot be increased to the desired treatment temperature T3 during the flash heating because there is a limit to the increase in temperature by means of the flash irradiation. For this reason, the two-stage flash heating comprised of the first flash heating process in which the temperature of the front surface of the semiconductor wafer W is increased at the first temperature increase rate and the second flash heating process in which the temperature of the front surface of the semiconductor wafer W is increased at the second temperature increase rate is performed in the present preferred embodiment. The first flash heating process has the technical significance of assist-heating by means of the flash irradiation from the flash lamps FL. Specifically, the first flash heating process increases the front surface temperature of the semiconductor wafer W from the preheating temperature T1 to the intermediate temperature T2, whereby the front surface temperature of the semiconductor wafer W is able to reach the treatment temperature T3 at the time of the second flash heating process. The subsequent second flash heating process has the same technical significance as the conventional flash heating, and increases the front surface temperature of the semiconductor wafer W to the treatment temperature T3 to activate the implanted impurities.

In other words, a shortage of preheating due to the low preheating temperature T1 is compensated for by the first flash heating process using the flash lamps FL. As compared to the halogen lamps HL which perform heating on the order of seconds, the flash heating using the flash lamps FL which perform heating on the order of milliseconds is able to significantly lower the amount of heat given to the semiconductor wafer W. Dotted lines in FIG. 10 indicate changes in temperature of the semiconductor wafer W when the preheating is performed only by the halogen lamps HL as in the conventional methods. As in the present preferred embodiment indicated by solid lines in FIG. 10, the preheating temperature T1 is suppressed to a low level by the halogen lamps HL, and the shortage of the preheating is compensated for by the first stage of the two-stage flash heating, whereby the amount of heat given to the semiconductor wafer W is significantly reduced as compared to the conventional methods (the dotted lines in FIG. 10).

If one-stage flash heating is used during the flash heating to increase the temperature of the front surface of the semiconductor wafer W from the preheating temperature T1 to the treatment temperature T3, the front surface temperature changes as indicated by dotted lines in FIG. 11. The two-stage flash heating (solid lines in FIG. 11) as in the present preferred embodiment is able to reduce the amount of heat given to the front surface of the semiconductor wafer W by the amount equivalent to the area of the triangle hatched in FIG. 11 as compared to the one-stage flash heating (the dotted lines in FIG. 11). In addition, as compared to the one-stage flash heating, the two-stage flash heating promotes more heat dissipation from the semiconductor wafer W because the light emitted from the flash lamps FL is reflected from the semiconductor wafer W to lower the degree of heating of surrounding environments including an atmosphere containing the treatment gas and components such as the inner walls of the chamber 6. In other words, the amount of heat given to the semiconductor wafer W is further reduced by the two-stage heating of the front surface of the semiconductor wafer W by means of the flash lamps FL after the halogen lamps HL heats the semiconductor wafer W to the preheating temperature T1 lower than the reaction temperature, as in the present preferred embodiment.

Further, the two-stage flash heating as in the present preferred embodiment is able to increase the temperature decrease rate of the semiconductor wafer W in the temperature decrease stage after the time t33 by not less than 20% and preferably in the range of 20% to 50%, as compared to the temperature decrease rate obtained when the front surface temperature of the semiconductor wafer W is increased from the preheating temperature T1 to the treatment temperature T3 by the one-stage flash heating. The increase in the temperature decrease rate prevents the inactivation of activated impurities.

While the preferred embodiment according to the present invention has been described hereinabove, various modifications of the present invention in addition to those described above may be made without departing from the scope and spirit of the invention. For example, although the two-stage flash heating is performed in the aforementioned preferred embodiment, three or more stages of flash heating may be performed after the preheating. In other words, a multi-stage flash heating may be performed which increases the temperature of the front surface of the semiconductor wafer W in multiple stages from the preheating temperature T1 to the treatment temperature T3. In the case of the multi-stage flash heating, the light emission pattern of the flash lamps FL should be such that the temperature increase rate of the front surface of the semiconductor wafer W is higher in later stages. More specifically, the ratio of the time interval equivalent to the pulse width to the time interval between the pulses in the pulse signal applied to the IGBTs 96 is set to be higher in later stages of the multi-stage flash heating. This further reduces the amount of heat given to the semiconductor wafer W.

In the aforementioned preferred embodiment, the heat treatment is performed on the semiconductor wafer W mainly composed of silicon. The present invention, however, is not limited to this. The semiconductor wafer W to be heat-treated may be mainly composed of germanium or silicon-germanium. Germanium is significantly lower in melting point than silicon. It is hence necessary to make the heating temperature of germanium during the heat treatment lower than that of silicon.

Specifically, the preheating temperature T1 during the heat treatment of the semiconductor wafer W mainly composed of germanium is between 100° C. and 400° C. For the two-stage flash heating of the semiconductor wafer W mainly composed of germanium, the intermediate temperature T2 is between 300° C. and 600° C. (preferably between 400° C. and 600° C.), and the treatment temperature T3 is between 600° C. and 900° C. For the heat treatment of the semiconductor wafer W mainly composed of silicon-germanium (50% silicon), the preheating temperature T1 is between 300° C. and 600° C. For the two-stage flash heating of the semiconductor wafer W mainly composed of silicon-germanium, the intermediate temperature T2 is between 600° C. and 900° C., and the treatment temperature T3 is between 900° C. and 1200° C.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiment, the filament-type halogen lamps HL are used as continuous lighting lamps that emit light continuously for not less than one second to perform the preheating of the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A method of irradiating a substrate with light to heat the substrate, said method comprising the steps of:
(a) irradiating said substrate with light from a continuous lighting lamp to heat said substrate to a preheating temperature lower than a reaction temperature at which a reaction occurs in said substrate; and
(b) irradiating a front surface of said substrate with a flash of light from a flash lamp to increase the temperature of said front surface in multiple stages to a treatment temperature higher than said reaction temperature so that the temperature increase rate of said front surface is higher in a later stage, said step (b) being performed after said step (a).

2. The method according to claim 1,
wherein said step (b) includes the steps of:
(b-1) irradiating said front surface of said substrate with a flash of light to increase the temperature of said front surface at a first temperature increase rate to an intermediate temperature; and
(b-2) irradiating said front surface of said substrate with a flash of light to increase the temperature of said front surface at a second temperature increase rate to said treatment temperature, said second temperature increase rate being higher than said first temperature increase rate, said step (b-2) being subsequent to said step (b-1).

3. The method according to claim 2,
wherein said substrate is mainly composed of silicon,
wherein said preheating temperature is between 400° C. and 700° C.,
wherein said intermediate temperature is between 600° C. and 1000° C., and
wherein said treatment temperature is between 1100° C. and 1300° C.

4. The method according to claim 2,
wherein said substrate is mainly composed of germanium,
wherein said preheating temperature is between 100° C. and 400° C.,
wherein said intermediate temperature is between 300° C. and 600° C., and
wherein said treatment temperature is between 600° C. and 900° C.

5. The method according to claim 2,
wherein said substrate is mainly composed of silicon-germanium,
wherein said preheating temperature is between 300° C. and 600° C.,
wherein said intermediate temperature is between 600° C. and 900° C., and
wherein said treatment temperature is between 900° C. and 1200° C.

6. The method according to claim 1, further comprising the step of
(c) decreasing the temperature of said substrate, said step (c) being performed after said step (b),
wherein a temperature decrease rate in said step (c) is 20% higher than that obtained when the temperature of said front surface of said substrate is increased in a single stage to said treatment temperature.
